(19) United States
(12) Patent Application Publication
(10) Pub. No.: US 2009/0021325 A1
(43) Pub. Date: Jan. 22, 2009

(54) FRONT-END MODULE

(75) Inventors: Jae CHAN LEE, Suwon (KR); Joong Han Yoon, Bucheon (KR); Gi Ho Han, Suwon (KR); Seok Min Woo, Suwon (KR); Dong Hyun Kim, Yongin (KR); Hyun Hak Kim, Osan (KR)

Correspondence Address: LOWE HAUPTMAN HAM & BERNER, LLP, 1700 DIAGONAL ROAD, SUITE 300, ALEXANDRIA, VA, 22314, US

(73) Assignee: Sumsung Electro-Mechanics Co., Ltd., Suwon (KR)

(21) Appl. No.: 12/176,173

(22) Filed: Jul. 18, 2008

(30) Foreign Application Priority Data
Jul. 20, 2007 (KR) 10-2007-72693

(51) Int. Cl. H03H 7/38

(52) U.S. Cl. 333/124

(57) ABSTRACT

A front end module is disclosed. The front end module includes a plurality of antennas receiving different frequency band signals, respectively, an impedance matching circuit unit comprising a plurality of tuners respectively connected to the plurality of antennas to control impedance matching, a selection unit selecting one frequency band signal from multiple frequency band signals passing through the impedance matching circuit unit, a measuring unit measuring signal strength of a received signal selected at the selection unit, and a control unit controlling an operation of the selection unit and an impedance of the tuner according to the signal strength of the received signal measured at the measuring unit.

### CROSS-REFERENCE TO RELATED APPLICATIONS

This application claims the priority of Korean Patent Application No. 2007-72693 filed on Jul. 20, 2007, in the Korean Intellectual Property Office, the disclosure of which is incorporated herein by reference.

### BACKGROUND OF THE INVENTION

1. Field of the Invention

The present invention relates to a front-end module, and more particularly, to a front-end module, which can select a reception frequency band and tune impedance matching according to received signal strength.

2. Description of the Related Art

The mobile communication technology has created a new communication culture based on rapid development of information communication technologies and economic growth. The mobile communication technology also provides various services for everyday life regardless of locations, such as personal mobile communication and information services, and personal financial services.

The development of the mobile communication technology has increased the number of subscribers to mobile communication systems. Therefore, a new scheme for mobile communications and multiple frequency bands have become necessary to cover demands of all the increasing subscribers. To this end, multi-band terminals that can selectively use multiple frequency bands are being required.

Also, when a broadband signal is received, a received signal needs to be fine tuned because reception sensitivity varies according to frequency.

Thus, there is a need for a front end module that selects one frequency band signal from multiple frequency band signals and finely tunes the selected signal so as to input an RF signal in an optimum state.

### SUMMARY OF THE INVENTION

An aspect of the present invention provides a front end module which can select a reception frequency band and fine-tune impedance matching according to received signal strength.

According to an aspect of the present invention, there is provided a front end module including: a plurality of antennas receiving different frequency band signals, respectively; an impedance matching circuit unit including a plurality of tuners respectively connected to the plurality of antennas to control impedance matching; a selection unit selecting one frequency band signal from multiple frequency band signals passing through the impedance matching circuit unit; a measuring unit measuring signal strength of a received signal selected at the selection unit; and a control unit controlling an operation of the selection unit and an impedance of the tuner according to the signal strength of the received signal measured at the measuring unit.

The impedance matching circuit unit may further include a plurality of inductor-capacitor (LC) oscillation circuits respectively connected to the plurality of antennas.

The tuner may include a Varactor diode.

The selection unit may include a switching circuit, and the switching circuit may perform switching only for a signal with a signal strength that is equal to or higher than a predetermined signal strength.

The measuring unit may include a received signal strength indicator (RSSI).

The control unit may include a voltage distributor. The voltage distributor may control an impedance of the tuner for a signal with a signal strength that is below a predetermined signal strength, and may control an operation of the selection unit and an impedance of the tuner for a signal with a signal strength that is equal to or higher than the predetermined signal strength.

The plurality of antennas may include: a first antenna receiving a high frequency band signal for European digital broadcasting reception; and a second antenna receiving a low frequency band signal.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram of a front end module according to an exemplary embodiment of the present invention;

FIG. 2 is a circuit diagram of a front end module according to another exemplary embodiment of the present invention; and

FIGS. 3A and 3B are graphs showing frequency characteristics according to received signal strength in respective reception paths at the front end module of FIG. 2.

### DETAILED DESCRIPTION OF THE PREFERRED EMBODIMENT

Exemplary embodiments of the present invention will now be described in detail with reference to the accompanying drawings.

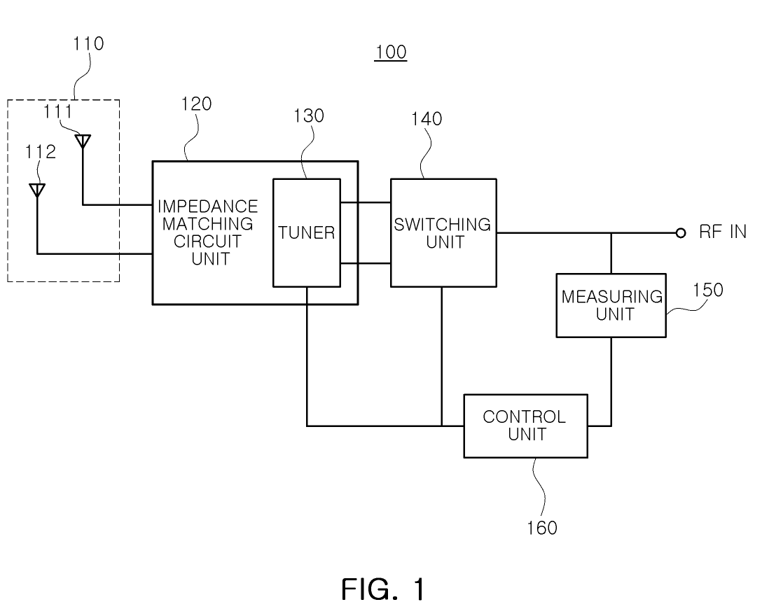

FIG. 1 is a block diagram of a front end module according to an exemplary embodiment of the present invention.

Referring to FIG. 1, the front end module 100 according to the current embodiment includes an antenna unit 110, an impedance matching circuit unit 120 including a tuner 130, a switching unit 140, a measuring unit 150 and a control unit 160.

The antenna unit 110 may include a plurality of antennas 111 and 112 that can receive signals of different frequency bands. According to the current embodiment, the antennas 111 and 112 may respectively receive a signal of a high frequency band, e.g., from about 600 MHz to about 775 MHz for European digital broadcasting reception, and a signal of a low frequency band, e.g., from about 475 MHz to about 550 MHz.

The antenna unit 110 may be connected with the impedance matching circuit unit 120.

The antennas 111 and 112 may be connected to impedance matching circuits, respectively. Each of the impedance matching circuits may be formed by connection of an inductor and a capacitor. The impedance matching circuit unit 120 may control an impedance of a signal received via each of the antennas 111 and 112, thereby compensating for loss caused by a change in frequency of the received signal.

The impedance matching circuit unit 120 may include a tuner 130 to finely tune the impedance matching.

The tuner 130 may change an impedance value of the impedance matching circuit unit 120 to fine tune a frequency characteristic of a signal passing through the impedance matching circuit unit 120. A varactor diode, a pin diode or the like may be used as the tuner 130. If the varactor diode is used, a capacitance value can be controlled. If the pin diode is used, a conductive line is also provided, so that an inductance value can be controlled due to a length expansion effect.

The tuner 130 can compensate for, e.g., a frequency change caused by a hand effect or surrounding changes, or a frequency null point of the antennas 111 and 112.

The switching unit 140 may select one of multiple signals received via each of the antennas 111 and 112 and having undergone impedance matching.

According to the current embodiment, the switching unit 140 may select one frequency band signal from different frequency band signals received via the two antennas 11 and 112. The switching unit 140 may control switching by controlling a voltage between both ends of a diode (hereinafter, referred to as a both-end voltage).

The one frequency band signal selected by the switching unit 140 may be input to a wireless device as a radio frequency (RF) input.

The measuring unit 150 may measure signal strength of the signal selected at the switching unit 140. The measuring unit 150 may include a received signal strength indicator (RSSI) The measuring unit 150 may convert the received analog signal into a digital signal, measure the strength of the digital signal at the RSSI, then convert the digital signal into an analog signal and send the analog signal to the control unit 160.

The control unit 160 may control the switching unit 140 and the tuner 130 according to the signal strength measured at the measuring unit 150.

The switching unit 140 can perform switching only when an input signal has a signal strength that is higher than a predetermined signal strength. That is, the control unit 160 controls the tuner 130 if the signal strength measured at the measuring unit 150 is insufficient to operate the switching unit 140. If the signal strength measured at the measuring unit 150 is high enough to operate the switching unit 140, the control unit 160 may control the switching unit 140 and the tuner 130.

Accordingly, a voltage of predetermined magnitude is needed to operate a switch of the switching unit 140. Thus, the switch of the switching unit 140 is set to select a first frequency band signal if a signal voltage measured at the measuring unit 150 is below the voltage of predetermined magnitude. In this case, the control unit 160 controls the tuner 130, so that fine impedance matching can be made.

If the signal voltage measured at the measuring unit 150 is equal to or higher than the voltage of predetermined magnitude, the switch of the switching unit 140 is switched to select a second frequency band signal and the control unit 160 controls the tuner 130, thereby performing impedance matching.

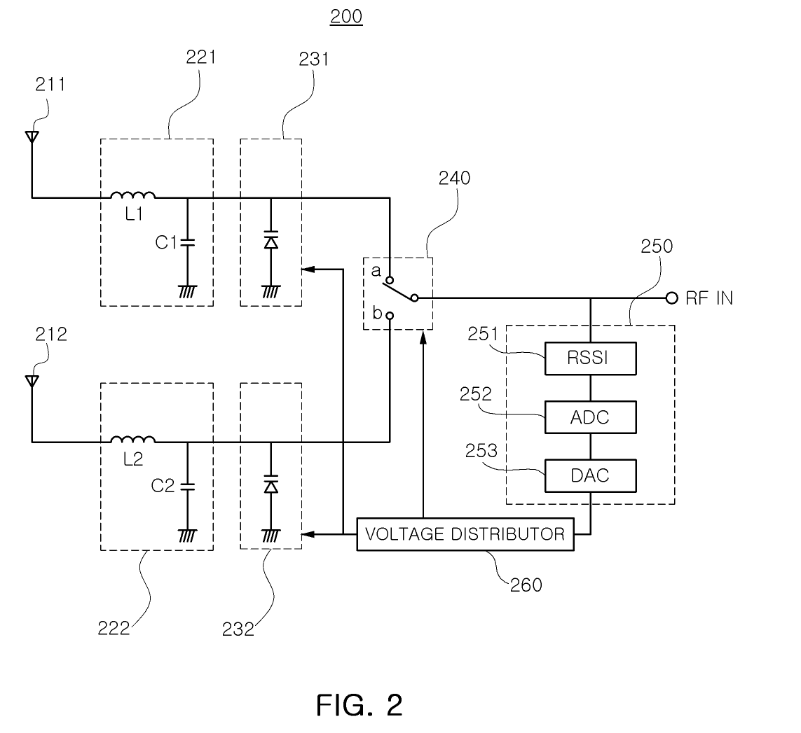

FIG. 2 is a circuit diagram of a front end module 200 according to another exemplary embodiment of the present invention.

Referring to FIG. 2, the front end module 200 according to the current embodiment includes a plurality of antennas 211 and 212, inductor-capacitor (LC) oscillation circuits 221 and 222, tuners 231 and 232, a switching unit 240, a measuring unit 250, and a voltage distributor 260.

The antennas 211 and 212 may receive respectively different frequency band signals. According to the current embodiment, the antennas 211 and 212 respectively receive a signal of a high frequency band, e.g., from about 600 MHz to about 775 MHz for European digital broadcasting reception, and a signal of a low frequency band, e.g., from about 475 MHz to about 550 MHz.

The antennas 211 and 212 may be connected to the LC oscillation circuits 221 and 222, respectively.

The LC oscillation circuit 221 may be formed by connection of an inductor L1 and a capacitor C1, and the LC oscillation circuit 222 may also be formed by connection of an inductor L2 and a capacitor C2. The LC oscillation circuits 221 and 222 may control impedances of signals received via the antennas 211 and 212, respectively, thereby compensating for signal loss caused by a change in frequency of the received signals.

The LC oscillation circuits 221 and 222 may be connected to the tuners 222 and 232 that can fine tune impedance matching, respectively.

The tuners 231 and 232 change capacitance values of the LC oscillation circuits 221 and 222, thereby fine tuning a frequency characteristic of signals passing through the LC oscillation circuits 221 and 222, respectively. According to the current embodiment, a varactor diode may be used as the tuner.

A capacitance value of the varactor diode may be changed by a control voltage applied to the varactor diode. The change in capacitance value of the varactor diode may also change a capacitance value of the LS oscillation circuit. Consequently, the impedance matching of a signal passing through the LC oscillation circuit can be performed.

The tuners 231 and 232 may compensate for a frequency change caused by a hand effect or surrounding changes, and a frequency null point of the antenna itself.

The switching unit 240 may select one frequency band signal from multiple frequency band signals received via the two antennas 211 and 212. The switching unit 240 may control switching by controlling a both-end voltage of a diode. According to the current embodiment, the switching of the switching unit 240 may be controlled according to a magnitude of a voltage input from the voltage distributor 260.

One frequency band signal selected at the switching unit 240 may be input to a wireless device as an RF input.

The measuring unit 250 may measure signal strength of a signal selected at the switching unit 240. The measuring unit 250 may include a received signal strength indicator (RSSI) 251.

In the measuring unit 250, an analog/digital converter (ADC) 252 may convert a received analog signal into a digital signal, the RSSI 251 may measure the signal strength of the digital signal, and a DA converter (DAC) 253 may convert the digital signal into an analog signal and send the analog signal to the voltage distributor 260.

The voltage distributor 260 may control the switching unit 240 and the tuners 231 and 232 according to signal strength measured at the measuring unit 250.

The switching unit 240 can perform switching only when an input signal has a signal strength that is higher than a predetermined signal strength. That is, if the signal strength measured at the measuring unit 250 is insufficient to operate the switching unit 240, the voltage distributor 260 controls the tuner 231. If the signal strength measured at the measuring unit 250 is high enough to operate the switching unit 240, the voltage distributor 260 may control the switching unit 240 and the tuner 232.

Accordingly, a voltage of predetermined magnitude is needed to operate a switch of the switching unit 240. Thus, the switch of the switching unit 240 is set to select a first frequency band signal ‘a’ if a signal voltage measured at the measuring unit 250 is below the voltage of predetermined magnitude. In this case, the voltage distributor 260 controls the tuner 231, so that fine impedance matching can be made.

If the signal voltage measured at the measuring unit 150 is equal to or higher than the voltage of predetermined magnitude, the switch of the switching unit 140 is switched to select a second frequency band signal ‘b’ and the voltage distributor 260 controls the tuner 232, thereby performing impedance matching.

According to the current embodiment, the switch of the switching unit 240 is set to select a first frequency band, and the predetermined magnitude of a voltage for operating the switch is set to 2.7 V. Accordingly, if the signal voltage measured at the measuring unit 250 is below 2.7 V, the switch may select a first frequency band signal. If the signal voltage measured at the measuring unit 250 is 2.7 V or higher, the switch of the switching unit may be switched to select a second frequency band signal.

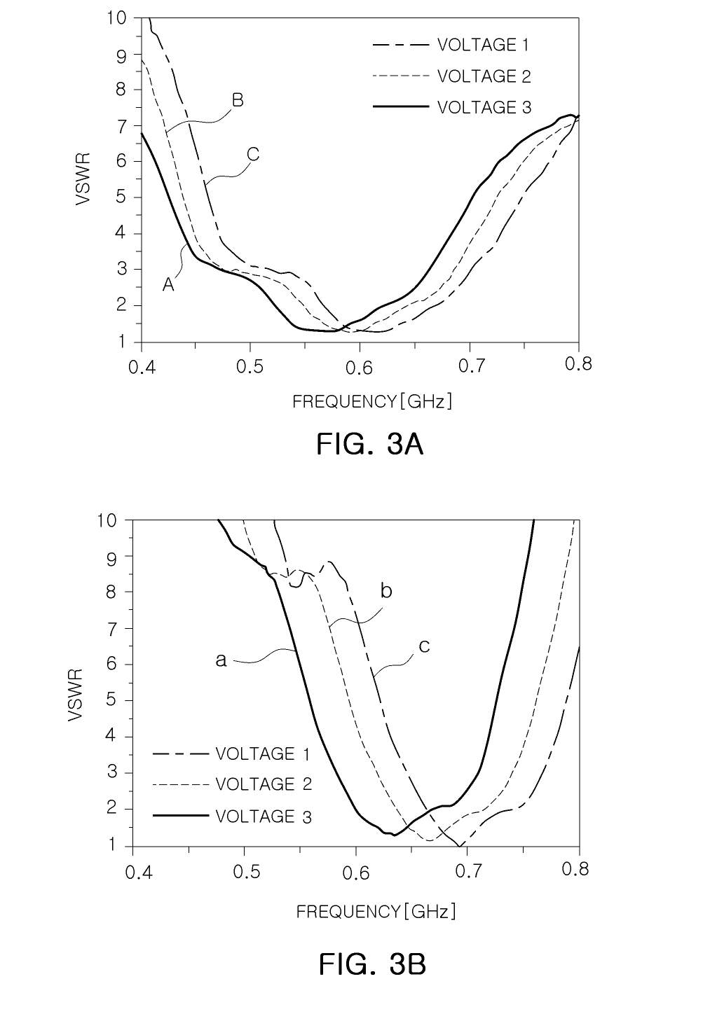

FIGS. 3A and 3B are graphs showing frequency characteristics according to the received signal strength at the front end module according to the exemplary embodiment of FIG. 2.

FIG. 3A shows a voltage standing wave ratio with respect to frequency according to signal strength measured at the measuring unit 250 when the first frequency band signal is selected.

In FIG. 3A, curves A, B and C respectively indicate frequency characteristics of received signals of Voltages 1, 2 and 3 each representing the signal strength measured at the measuring unit 250. As shown in FIG. 3A, the frequency characteristics vary according to the received signal strength, which is measured at the measuring unit 250, and the tuner 231 performs tuning to make the different frequency characteristics identical to one another.

According to the current embodiment, impedance matching is tuned with reference to the case where a voltage of the received-signal strength measured at the measuring unit 250 is Voltage 2 in FIG. 3A. That is, the tuner 231 may be controlled to shift the curves A and C indicating the frequency characteristics in the cases of Voltages 1 and 3 with reference to the curve B of Voltage 2 representing the received-signal strength measured at the measuring unit 250.

FIG. 3B shows a voltage standing wave ratio with respect to frequency according to the received signal strength measured at the measuring unit 250 when the second frequency band signal is selected.

In FIG. 3B, curves a, b and c indicate frequency characteristics of received signals of Voltages 1, 2 and 3 representing the signal strength measured at the measuring unit 250. As shown in FIG. 3B, the frequency characteristics vary according to the received signal strength, which is measured at the measuring unit 250, and the tuner 232 performs tuning to make the different frequency characteristics identical to one another.

According to the current embodiment, impedance matching is tuned with reference to the case where the voltage of the received-signal strength measured at the measuring unit 250 is Voltage 2. That is, the tuners 231 and 232 may be controlled to shift the curves a and c indicating the frequency characteristics in the cases of Voltages 1 and 3 with reference to the curve b in the case of Voltage 2 representing the received-signal strength measured at the measuring unit 250.

Through this tuning, compensation can be made for the frequency characteristics according to the difference in received-signal strength in the same reception path.

While the present invention has been shown and described in connection with the exemplary embodiments, it will be apparent to those skilled in the art that modifications and variations can be made without departing from the spirit and scope of the invention as defined by the appended claims.

What is claimed is:

1. A front end module comprising:
a plurality of antennas receiving different frequency band signals, respectively;
an impedance matching circuit unit comprising a plurality of tuners respectively connected to the plurality of antennas to control impedance matching;
a selection unit selecting one frequency band signal from multiple frequency band signals passing through the impedance matching circuit unit;
a measuring unit measuring signal strength of a received signal selected at the selection unit; and
a control unit controlling an operation of the selection unit and an impedance of the tuner according to the signal strength of the received signal measured at the measuring unit.

2. The front end module of claim 1, wherein the impedance matching circuit unit further comprises a plurality of inductor-capacitor (LC) oscillation circuits respectively connected to the plurality of antennas.

3. The front end module of claim 1, wherein the tuner comprises a Varactor diode.

4. The front end module of claim 1, wherein the selection unit comprises a switching circuit.

5. The front end module of claim 4, wherein the switching circuit performs switching only for a signal with a signal strength that is equal to or higher than a predetermined signal strength.

6. The front end module of claim 1, wherein the measuring unit comprises a received signal strength indicator (RSSI).

7. The front end module of claim 1, wherein the control unit comprises a voltage distributor.

8. The front end module of claim 7, wherein the voltage distributor controls an impedance of the tuner for a signal with a signal strength that is below a predetermined signal strength, and controls an operation of the selection unit and an impedance of the tuner for a signal with a signal strength that is equal to or higher than the predetermined signal strength.

9. The front end module of claim 1, wherein the plurality of antennas comprise:
a first antenna receiving a high frequency band signal for European digital broadcasting reception; and
a second antenna receiving a low frequency band signal.
